(19) United States
(12) Patent Application Publication
(10) Pub. No.: US 2006/0164819 A1
(43) Pub. Date: Jul. 27, 2006

(54) Circuit board with plug connector

(75) Inventor: Jorg Romahn, Berlin (DE)

Correspondence Address: MORRISON & FOERSTER LLP, 1650 TYSONS BOULEVARD, SUITE 300, MCLEAN, VA, 22102, US

(73) Assignee: Siemens Aktiengesellschaft, Munchen (DE)

(21) Appl. No.: 10/503,606

(22) PCT Filed: Dec. 2, 2003
(86) PCT No.: PCT/DE03/04000

§ 371 Date: Jul. 19, 2005

(30) Foreign Application Priority Data
Dec. 9, 2002 (DE) 102 19 377.2

(51) Int. Cl. H05K 7/08

(52) U.S. Cl. 361/760

(57) ABSTRACT

Printed circuit board having a plug connection The present invention relates to a printed circuit board for a radio module which has a connection on the printed circuit board side having contact points for selectively connecting a plug from a number of plugs of a predetermined plug type which have various contact points fitted to them, it being possible, depending on the selection of the plug from the number of plugs which have various contact points fitted to them, to fit a plug-specific selection of contact points of the connection on the printed circuit board side.

The invention relates to a printed circuit board, which has a connection on the printed circuit board side having contact points for a plug of a predetermined plug type.

Printed circuit boards of this type are known, for example, in conventional radio modules for access to an interface. In this case, for example, contact may be made with radio modules by means of a so-called board-to-board plug (B2B plug), a zero insertion force plug (ZIF plug), a pin-type plug or another type of plug. A user may select one from the various alternatives.

It is known to equip a radio module with a printed circuit board, whose conductor track structure has only one connection having contact points for a single plug of a predetermined plug type. A plug has a specific pin width which corresponds to a specific number and arrangement of contact points. A connection having contact points for a specific plug of a plug type accordingly likewise has a specific pin width. If other plugs of the same plug type but having a different pin width than precisely this predetermined pin width are to be used, another printed circuit board having a conductor track structure must be used which has a connection having contact points for a plug having this other pin width. This means that different printed circuit boards must be provided separately, each having a connection having contact points for a plug having a predetermined pin width of a predetermined plug type. In this case, a large number of different variants of printed circuit boards needs to be produced. This also involves high costs.

Making contact between a plug and a printed circuit board activates specific performance features as a function of the respectively used contact points or the pin width of the plug. Depending on the performance features, it may be expedient in this case not to offer every performance feature to every customer of a radio module. This is used, for example, when pricing a corresponding product. When developing a radio module, account must therefore be taken of the fact that not every performance feature is made available to a customer. In this connection, until now, plugs having a different pin width have had to be split up on different printed circuit boards. The various pin widths in this case correspond to a different functional pin assignment of the plug, i.e. the number of pins is to be matched to the available or offered performance features. As a result, the costs of a printed circuit board as a component are increased both in terms of the development complexity and in terms of the logistical complexity.

The invention is based on the object of identifying a printed circuit board which is compatible with plugs having a different pin width of a predetermined plug type, i.e. such that it can easily have plugs having a different pin width fitted to it and is at the same time optimized in the terms of material costs.

This object is achieved according to the invention by a printed circuit board according to claim 1. Further advantageous embodiments are described in the subclaims.

According to claim 1, a printed circuit board is provided for a radio module which has a connection on the printed circuit board side having contact points for selectively connecting a plug from a number of plugs of a predetermined plug type which have various contact points fitted to them, it being possible, depending on the selection of the plug from the number of plugs which have various contact points fitted to them, to fit a plug-specific selection of contact points of the connection on the printed circuit board side.

In the context of the present invention, plugs which have various contact points fitted to them are to be understood to mean plugs having a different functional pin assignment and number of pins. This usually corresponds to a different pin width of the corresponding plugs.

In one preferred embodiment of the printed circuit board according to the invention, the plug-specific selection of contact points of the connection on the printed circuit board side corresponds to a specific group of performance features.

All performance features are preferably offered on a printed circuit board according to the invention. In accordance with the plugs which have various contact points fitted to them or the different pin widths of the plugs, all performance features in various groups of performance features are offered. In this case, the development of a printed circuit board need only be one which minimizes the costs of the printed circuit board, the complexity of the printed circuit board in terms of logistics, and the development complexity.

In a further preferred embodiment of the printed circuit board according to the invention, the printed circuit board may be used for a mobile radio device, in particular a GSM or UMTS radio device.

In addition, the predetermined plug type is preferably a plug type from the group consisting of: board-to-board plugs (B2B plugs), zero insertion force plugs (ZIF plugs), pin-type plugs.

The pin assignment of a plug should be geared to the performance features offered on the printed circuit board by means of the corresponding contact points.

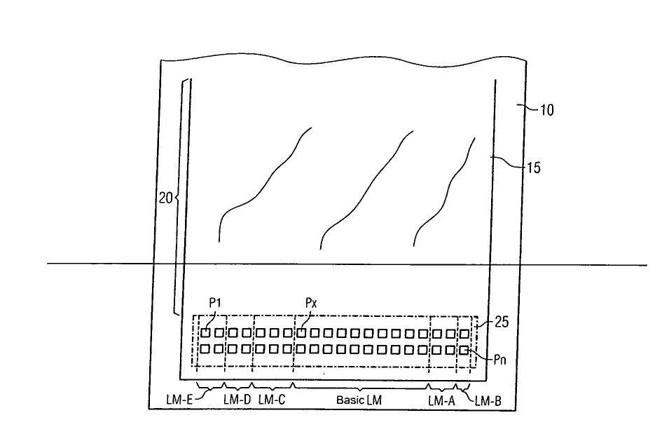

For the purpose of illustrating the invention, FIG. 1 shows an exemplary embodiment of a printed circuit board according to the invention.

In FIG. 1, the printed circuit board has the reference numeral 10. Visible on the printed circuit board 10 is a conductor track structure 15 which is formed by etching steps in metallic conductor track layers on the printed circuit board 10. The conductor track structure 15 in this case comprises a so-called circuit region 20 and a connection region 25 provided and suitable for connecting plugs.

The connection region 25 comprises a large number of contact points or pins P1-Pn. A specific selection of pins or a specific group of pins represents a specific performance feature LM. Making contact between a plug and a group of pins determined as a function of the pin assignment of the plug activates one or more performance features. In the present example, various performance features are shown. In the center of the connection region 25, 20 pins represent a basic feature “basic LM”.

If contact is made between these 20 pins and a plug having the corresponding pin width, the performance feature “basic LM” is activated.

Four further contact points or pins, which adjoin the performance feature “basic LM” on the right, represent a further performance feature LM-A. A suitable 24-pole plug may thus activate the performance features “basic LM+LM-A”. By adding two further pins, the performance features “basic LM+LM-A+LM-B” can be realized. If a plug has six pins, and contact can be made between these six pins and the six contact points to the left of the contact points representing the performance feature “basic LM”, in this case the performance features “basic LM+LM-C” are activated. In this case, a corresponding 26-pole plug would have to be used.

A plug, with which all of the available performance features could be activated, would in this example have to have 40 poles. It would then be possible using such a plug to realize the performance features “basic LM+LM-C+LM-D+LM-E+LM-A+LM-B”.

Such a printed circuit board 10 may be used in a very flexible manner.

The printed circuit board shown in FIG. 1 may be used, for example, in mobile radio devices, in particular in GSM or UMTS mobile radio devices.

1. A printed circuit board for a radio module which has a connection on the printed circuit board side, comprising contact points for selectively connecting a plug from a number of plugs of a predetermined plug type which have various contact points fitted thereto, and, depending on the selection of the plug from the number of plugs which have various contact points fitted thereto, fitting a plug-specific selection of contact points of the connection on the printed circuit board side.

2. The printed circuit board as claimed in claim 1, wherein the plug-specific selection of contact points of the connection on the printed circuit board side corresponds to a specific group of performance features.

3. The printed circuit board as claimed in claim 1, wherein the printed circuit board is configured for use as a mobile radio device.

4. The printed circuit board as claimed in claim 1, wherein the predetermined plug type is a plug type from the group consisting of: board-to-board plugs, zero insertion force plugs, pin-type plugs.
